(19) United States
(12) Patent Application Publication
(10) Pub. No.: US 2008/0006882 A1
(43) Pub. Date: Jan. 10, 2008

(54) Spiral Inductor with High Quality Factor of Integrated Circuit

(75) Inventor: Yung-Sheng Huang, Taipei City (TW)

Correspondence Address: WPAT, PC, 7225 BEVERLY ST., ANNANDALE, VA, 22003, US

(73) Assignee: HOLTEK SEMICONDUCTOR, INC., Hsinchu (TW)

(21) Appl. No.: 11/468,105

(22) Filed: Aug. 29, 2006

(30) Foreign Application Priority Data
Jul. 7, 2006 (TW) 095124730

(51) Int. Cl. H01L 29/76

(52) U.S. Cl. 257/379

(57) ABSTRACT

A spiral inductor with high quality factor for an integrated circuit (IC) is disclosed, in which the metal layers arranged under a spiral inductor layer are parallel-connected to each other by the use of interconnects so as to increase the thickness of the metal layer and thus effectively reduce the parasitic resistance of the spiral inductor. In a preferred aspect, the parasitic resistance of the spiral inductor is reduced by increasing the interconnects, used for connecting the spiral inductor layer and the metal layer arranged underneath the same. In another preferred aspect, an interconnect is formed under the spiral inductor layer while enabling the same to be disconnected from the metal layer directly under the spiral inductor layer, by which the quality factor of the spiral inductor is increased since the substantial sectional area of the spiral inductor layer is increased and thus the parasitic resistance of the spiral inductor is decreased.

### FIELD OF THE INVENTION

The present invention relates to a spiral inductor formed by a semiconductor process, and more particularly, to an integrated circuit spiral inductor with high quality factor that is applicable to a radio frequency integrated circuit (RFIC).

### BACKGROUND OF THE INVENTION

Please refer to FIG. 1 and FIG. 2, which are respectively a top view and an a-a′ sectional view of a conventional spiral inductor of RFIC. Generally, a conventional RFIC may include a substrate, a plurality of metal layers, and a plurality of insulation layers. In the example shown in FIG. 1 and FIG. 2, the RFIC 1 is a six-layer stack formed on a substrate 101, each layer being composed of an insulation layer and a metal layer, whereas, from the top to the bottom adjacent to the substrate 101, the six-layer stack is composed of a first insulation layer 102, a first metal layer 103, a second insulation layer 104, a second metal layer 105, a third insulation layer 106, a third metal layer 107, a fourth insulation layer 108, a fourth metal layer 109, a fifth insulation layer 110, a fifth metal layer 111, a sixth insulation layer 112 and a sixth metal layer 113. Within the stack of the RFIC 1, the first metal layer 103 is patterned to be used as a spiral inductor of spiral figure, in that the first wire 1031 and the second wire 1032 are electrically connected to the second metal layer 105 respectively by the first interconnect 1041 and the second interconnect 1042, as the shadowed square on the left is the first interconnect 1041 while the shadowed square on the right is the second interconnect 1042. It is noted that the length L of the first interconnect is designed to equal to the width W of the wire connected thereto. Moreover, in order to reduce the parasitic resistance caused by skin effect, the thickness of the first metal layer 103 is enabled to be thicker than other metal layers. However, as the thickness of the second metal layer 105 is not specifically thickened, the parasitic resistance is increasing as the turn of the spiral inductor is increasing that results in the decrease of quality factor and further adversely affect the signal quality of the RFIC 1.

Therefore, it is in need of an on-chip spiral inductor with high quality factor that is free from the shortcomings of prior art.

### SUMMARY OF THE INVENTION

It is the primary object of the present invention to provide an integrated circuit spiral inductor, which is capable of increasing its quality factor by reducing the parasitic resistance of the spiral inductor through the use of interconnects for parallel-connecting an inductor layer of the spiral inductor with a metal layer formed underneath the inductor layer.

It is another object of the invention to provide an integrated circuit spiral inductor, which is capable of increasing its quality factor by reducing the parasitic resistance of the spiral inductor through the increase of an area of interconnects used for connecting an inductor layer and a metal layer formed underneath the same.

It is yet another object of the invention to provide an integrated circuit spiral inductor, having an interconnect formed underneath its inductor layer while being disconnected to a metal layer underneath the inductor layer, by which the sectional area of the inductor layer is increased so that the quality factor of the spiral inductor can be increased since the parasitic resistance thereof is reduced.

To achieve the above objects, the present invention provides an integrated circuit spiral inductor of high quality factor, which is substantially a stack of at least four layers formed on a substrate by a semiconductor process, each layer being composed of an insulation layer and a metal layer; wherein, a first metal layer, being the topmost metal layer of the aforesaid metal layers and patterned to be an inductor of spiral figure, is the thickest layer among those metal layers and has at least a first and a second wires, being electrically connected to a second metal layer respectively by a first interconnect and a second interconnect; and a second metal layer is parallel-connected to a third metal layer through a third interconnect, whereas the second metal layer is the metal layer right under the first metal layer and the third metal layer is the metal right under the second metal layer.

Preferably, the semiconductor process is a process selected form the group consisting of a CMOS process, a BiCMOS process, a SiGe process, a GaAs process; and the substrate can be made of a material selected from the group consisting of silicon (Si), gallium arsenide (GaAs), and silicon germanium (SiGe); and each insulation layer can be made of a material selected from the group consisting of silicon dioxide (SiO2) and silicon nitride.

Preferably, the inductor of spiral figure is patterned following a shape selected from the group consisting of a circle, a square, and an octagon.

Preferably, a length of the surface area of the first interconnect is larger than a width of the first wire.

Preferably, a fourth interconnect is formed underneath the first metal layer while being disconnected to the second metal layer.

To achieve the above objects, the present invention provides an integrated circuit spiral inductor of high quality factor, which is substantially a stack of at least five layers formed on a substrate by a semiconductor process, each layer being composed of an insulation layer and a metal layer; wherein, a first metal layer, being the topmost metal layer of the aforesaid metal layers and patterned to be an inductor of a first spiral figure, is the thickest layer among those metal layers and has at least a first and a second wires; and a second metal layer, being the metal layer right under the first metal layer and patterned to be another inductor of a second spiral figure, has at least a third and a fourth wires; and the first and the second wires are respectively parallel-connected to the third and the fourth wires through a first interconnect and the third and the fourth wires are electrically connected to a third metal layer respectively by a second interconnect and a third interconnect while the third metal layer is parallel-connected to a fourth metal layer through a fourth interconnect, whereas the third metal layer is the metal layer right under the second metal layer and the fourth metal layer is a metal right under the third metal layer.

Preferably, the semiconductor process is a process selected form the group consisting of a CMOS process, a BiCMOS process, a SiGe process, a GaAs process; and the substrate can be made of a material selected from the group consisting of silicon (Si), gallium arsenide (GaAs), and silicon germanium (SiGe); and each insulation layer can be made of a material selected from the group consisting of silicon dioxide (SiO2) and silicon nitride.

Preferably, the inductor of the first spiral figure is patterned following a shape selected from the group consisting of a circle, a square, and an octagon; and same to the inductor of the second spiral figure.

Preferably, a length of the surface area of the second interconnect is larger than a width of the third wire.

Preferably, a fifth interconnect is formed underneath the second metal layer while being disconnected to the third metal layer.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is a top view of a conventional spiral inductor of RFIC.

FIG. 2 is an a-a′ sectional view of FIG. 1.

FIG. 3 is a top view of an integrated circuit spiral inductor according to a first preferred embodiment of the invention.

FIG. 4 is an a-a′ sectional view of FIG. 3.

FIG. 5 is a top view of an integrated circuit spiral inductor according to a second preferred embodiment of the invention.

FIG. 6 is an a-a′ sectional view of FIG. 5.

FIG. 7 is a b-b′ sectional view of FIG. 6.

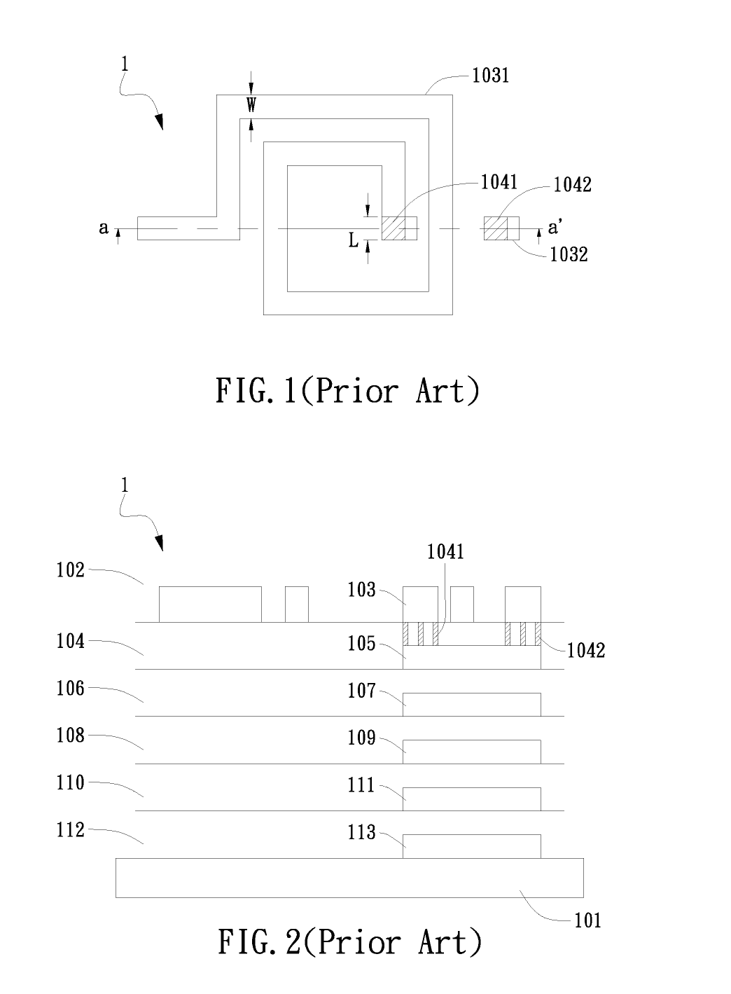

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

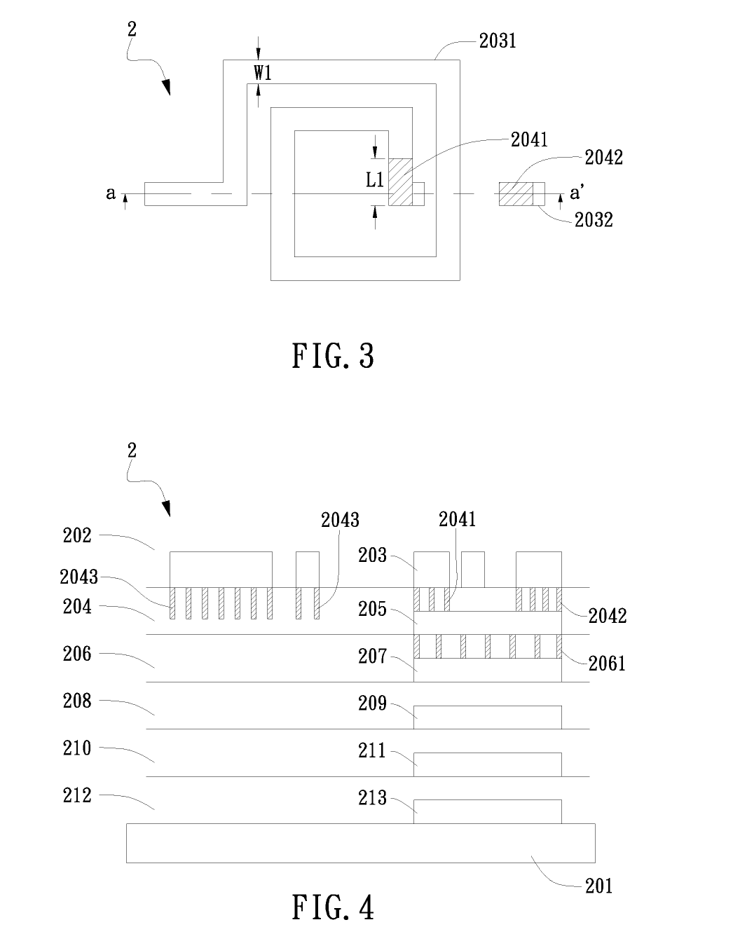

Please refer to FIG. 3 and FIG. 4, which are respectively a top view and an a-a′ sectional view of an integrated circuit spiral inductor according to a first preferred embodiment of the invention. It is known that a standard RFIC 2 is a six-layer stack formed on a substrate 201, each layer being composed of a SiO2 insulation layer and a metal layer, whereas, from the top to the bottom adjacent to the substrate 201, the six-layer stack is composed of a first insulation layer 202, a first metal layer 203, a second insulation layer 204, a second metal layer 205, a third insulation layer 206, a third metal layer 207, a fourth insulation layer 208, a fourth metal layer 209, a fifth insulation layer 210, a fifth metal layer 211, a sixth insulation layer 212 and a sixth metal layer 213. In the first embodiment of the invention, the first metal layer 203, being the topmost metal layer of the aforesaid metal layers, is the thickest layer among those metal layers; and it has a first wire 2031 and a second wire 2032, cooperatively forming an inductor of spiral figure. Moreover, a plurality of via holes 204 are formed on the second insulation layer 204 at positions underneath the two wires 2031, 2032 that are used for forming a first and a second interconnects 2041, 2042. Thus, the first and the second wires 2031, 2032 are connected to the second metal layer 205 respectively through the first interconnect 2041 and the second interconnect 2042 while preventing shortage. In addition, for reducing parasitic resistance, a plurality of via holes are formed on the third insulation layer 206, being sandwiched between the second metal layer 205 and the third metal layer 207, for forming a third interconnect 2061 therein. Thus, the second metal layer 205 can be parallel-connected to the third metal layer 207 through the third interconnect 2061 such that the quality factor of the spiral inductor is enhanced as the parasitic resistance is effectively reduce for the metal layer of the spiral inductor is thickened by the parallel-connected structure. As the shadowed square on the left of FIG. 3 is the first interconnect 2041 while the shadowed square on the right is the second interconnect 2042, it is noted that the length L1 of the first interconnect 2041 is designed to be larger than the width W1 of the first wire 2031 connected thereto, thereby, the area of interconnects used for connecting the first wire 2031 and the second metal layer 205 is increased so that the parasitic resistance can be reduced. Furthermore, a fourth interconnect 2043 is formed underneath the first metal layer 203 at a position where the first metal layer 203 is not electrically connected to the second metal layer 205, by which the sectional area of the first metal layer 203 is increased so that the quality factor of the spiral inductor can be increased since the parasitic resistance thereof is reduced.

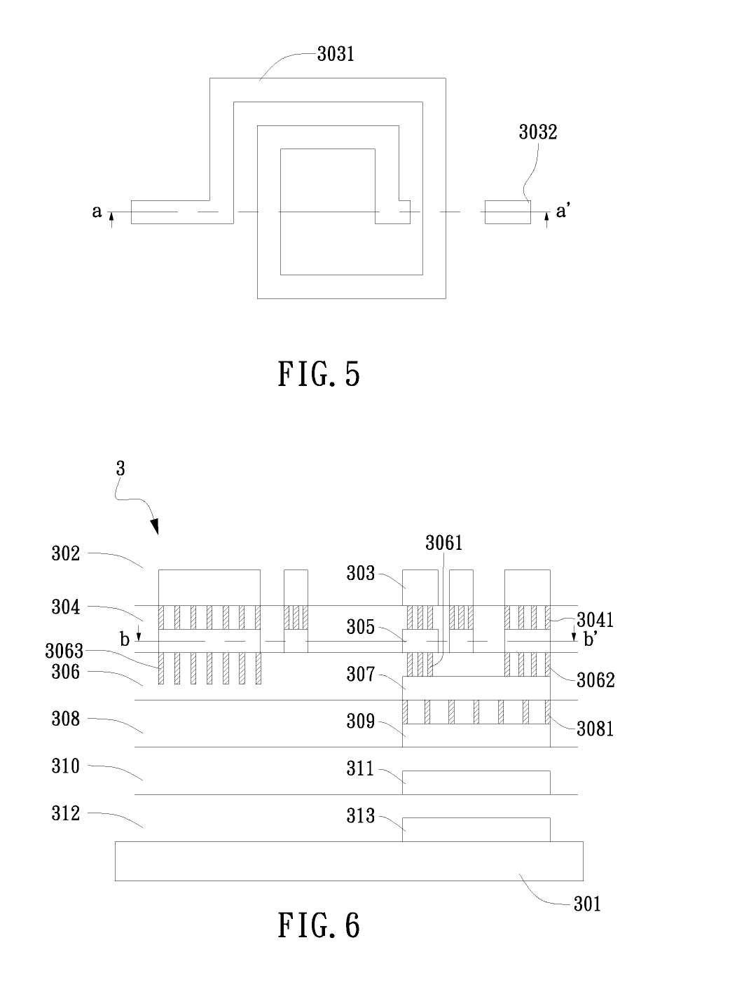

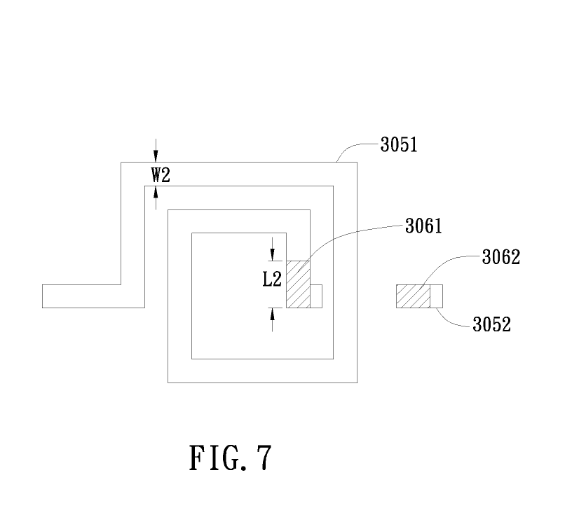

Please refer to FIG. 5, FIG. 6 and FIG. 7, which are respectively a top view, and an a-a′ sectional view of an integrated circuit spiral inductor according to a second preferred embodiment of the invention, whereas FIG. 7 is a b-b′ sectional view of FIG. 6. It is known that a standard RFIC 3 is a six-layer stack formed on a substrate 301, each layer being composed of a SiO2 insulation layer and a metal layer, whereas, from the top to the bottom adjacent to the substrate 301, the six-layer stack is composed of a first insulation layer 302, a first metal layer 303, a second insulation layer 304, a second metal layer 305, a third insulation layer 306, a third metal layer 307, a fourth insulation layer 308, a fourth metal layer 309, a fifth insulation layer 310, a fifth metal layer 311, a sixth insulation layer 312 and a sixth metal layer 313. Similarly, in the second embodiment of the invention, the first metal layer 303, being the topmost metal layer of the aforesaid metal layers, is the thickest layer among those metal layers. Furthermore, the first metal layer 303 has a first wire 3031 and a second wire 3032, cooperatively forming a spiral figure thereon while the second metal layer 305 has a third wire 3051 and fourth wire 3052, cooperatively forming another spiral figure thereon similar to the prior spiral figure. Moreover, a plurality of via holes 304 are formed on the second insulation layer 304 at positions underneath the two wires 3031, 3032 that are used for forming a first interconnect 3041. Thus, the first and the second wires 3031, 3032 are connected parallelly to the third and the fourth wires 3051, 3052 of the second metal layer 305 respectively through the first interconnect 3041, such that the quality factor of the spiral inductor is enhanced as the parasitic resistance is effectively reduce for the metal layer of the spiral inductor is thickened by the parallel-connected structure.

In addition, a plurality of via holes are formed on the third insulation layer 306 at positions underneath the third and the fourth wires 3051, 3052 that are used for forming a second interconnect 3061 and a third interconnect 3062. Thus, the third and the fourth wires 3051, 3052 are connected to the third metal layer 307 respectively through the second interconnect 3061 and the third interconnect 3062 while preventing shortage, such that the quality factor of the spiral inductor is enhanced as the parasitic resistance is effectively reduce for the metal layer of the spiral inductor is thickened by the parallel-connected structure. Moreover, for reducing parasitic resistance, a plurality of via holes are formed on the fourth insulation layer 308 for forming a fourth interconnect 3081 therein. Thus, the third metal layer 307 can be parallel-connected to the fourth metal layer 309 through the fourth interconnect 3081 such that the quality factor of the spiral inductor is enhanced as the parasitic resistance is effectively reduce for the metal layer of the spiral inductor is thickened by the parallel-connected structure. As the shadowed square on the left of FIG. 7 is the second interconnect 3061, it is noted that the length L2 of the second interconnect 3061 is designed to be larger than the width W2 of the third wire 3051 connected thereto, thereby, the area of interconnects used for connecting the third wire 3051 and the third metal layer 307 is increased so that the parasitic resistance can be reduced. Furthermore, a fifth interconnect 3063 is formed underneath the second metal layer 305 at a position where the second metal layer 305 is not electrically connected to the third metal layer 307, by which the sectional area of the second metal layer 305 is increased so that the quality factor of the spiral inductor can be increased since the parasitic resistance thereof is reduced.

Although the spiral figure shown in the abovementioned embodiments is patterned following a shape of a square, it is only used as illustration and is not limited thereby, It is noted that the spiral figure can be patterned following a shape selected from the group consisting of a circle, a square, and an octagon, etc. Moreover, the substrate can be made of silicon (Si), gallium arsenide (GaAs), silicon germanium (SiGe), or other semiconductor materials; and each insulation layer can be made of silicon dioxide (SiO2), silicon nitride, or other insulating materials. Last but not least, the semiconductor process used for manufacturing the aforesaid integrated circuit spiral inductor can be a process selected form the group consisting of a CMOS process, a BiCMOS process, a SiGe process, a GaAs process, with respect to the substrate of the integrated circuit spiral inductor. That, the forgoing variations are known to those skilled in the art and thus are not described further herein.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An integrated circuit spiral inductor of high quality factor, being substantially a stack of at least four layers formed on a substrate by a semiconductor process, each layer being composed of an insulation layer and a metal layer; wherein a first metal layer, being the topmost metal layer of the aforesaid metal layers and patterned to be an inductor of spiral figure, is the thickest layer among those metal layers and has at least a first and a second wires, being electrically connected to a second metal layer respectively by a first interconnect and a second interconnect; and a second metal layer is parallel-connected to a third metal layer through a third interconnect, whereas the second metal layer is the metal layer right under the first metal layer and the third metal layer is the metal right under the second metal layer.

2. The integrated circuit spiral inductor of claim 1, wherein the semiconductor process is a process selected form the group consisting of a CMOS process, a BiCMOS process, a SiGe process, a GaAs process.

3. The integrated circuit spiral inductor of claim 1, wherein the substrate is made of a material selected from the group consisting of silicon (Si), gallium arsenide (GaAs), and silicon germanium (SiGe).

4. The integrated circuit spiral inductor of claim 1, wherein the inductor of spiral figure is patterned following a shape selected from the group consisting of a circle, a square, and an octagon.

5. The integrated circuit spiral inductor of claim 1, wherein a length of the surface area of the first interconnect is larger than a width of the first wire.

6. The integrated circuit spiral inductor of claim 1, wherein a fourth interconnect is formed underneath the first metal layer while being disconnected to the second metal layer.

7. An integrated circuit spiral inductor of high quality factor, which is substantially a stack of at least five layers formed on a substrate by a semiconductor process, each layer being composed of an insulation layer and a metal layer; wherein, a first metal layer, being the topmost metal layer of the aforesaid metal layers and patterned to be an inductor of a first spiral figure, is the thickest layer among those metal layers and has at least a first and a second wires; and a second metal layer, being the metal layer right under the first metal layer and patterned to be another inductor of a second spiral figure, has at least a third and a fourth wires; and the first and the second wires are respectively parallel-connected to the third and the fourth wires through a first interconnect and the third and the fourth wires are electrically connected to a third metal layer respectively by a second interconnect and a third interconnect while the third metal layer is parallel-connected to a fourth metal layer through a fourth interconnect, whereas the third metal layer is the metal layer right under the second metal layer and the fourth metal layer is a metal right under the third metal layer.

8. The integrated circuit spiral inductor of claim 7, wherein the semiconductor process is a process selected form the group consisting of a CMOS process, a BiCMOS process, a SiGe process, a GaAs process.

9. The integrated circuit spiral inductor of claim 7, wherein the substrate is made of a material selected from the group consisting of silicon (Si), gallium arsenide (GaAs), and silicon germanium (SiGe).

10. The integrated circuit spiral inductor of claim 7, wherein the inductor of the first spiral figure is patterned following a shape selected from the group consisting of a circle, a square, and an octagon; and same to the inductor of the second spiral figure.

11. The integrated circuit spiral inductor of claim 7, wherein a length of the surface area of the second interconnect is larger than a width of the third wire.

12. The integrated circuit spiral inductor of claim 7, wherein a fifth interconnect is formed underneath the second metal layer while being disconnected to the third metal layer.
